(19) United States
(12) Patent Application Publication
(10) Pub. No.: US 2022/0186360 A1
(43) Pub. Date: Jun. 16, 2022

(54) IMPROVED VAPOUR DEPOSITION SYSTEM, METHOD AND MOISTURE CONTROL DEVICE

(71) Applicant: XEFCO PTY LTD, Eveleigh NSW (AU)

(72) Inventors: Thomas HUSSEY, Drummoyne, New South Wales (AU); Brian CONOLLY, Northwood, New South Wales (AU); Scott WHITBY, Chatswood, New South Wales (AU)

(21) Appl. No.: 17/436,488

(22) PCT Filed: Mar. 4, 2020
(86) PCT No.: PCT/AU2020/050203

§ 371 Date: Sep. 3, 2021

(30) Foreign Application Priority Data
Mar. 5, 2019 (AU) 2019900723

(51) Int. Cl. C23C 14/56; C23C 14/24; C23C 14/02; C23C 14/34; C23C 14/54; C23C 14/58

(52) U.S. Cl. CPC C23C 14/562; C23C 14/24; C23C 14/58; C23C 14/34; C23C 14/54; C23C 14/02

(57) ABSTRACT

A system for treating a substrate comprising an unwinder adapted to receive and unwind a roll of substrate and a rewinder adapted to rewind the substrate from the unwinder. The system further comprising a physical vapour deposition (PVD) apparatus, a vacuum chamber in which the unwinder, PVD apparatus and rewinder are disposed; and wherein a coating drum of the PVD apparatus has a temperature of between 0° C. and 10° C., and is adapted to increase a desorption rate of the substrate.

### TECHNICAL FIELD

The present disclosure relates to a system and process for improving vapour deposition of substrates. More particularly, the present disclosure relates to a system and process for an improved vapour deposition which may provide for superior deposition bonding to a substrate.

### BACKGROUND

Physical vapour deposition (PVD), plasma enhanced physical vapour deposition (PEPVD), chemical vapour deposition (CVD) and plasma enhanced chemical vapour deposition (PECVD) are known processes for depositing a material or chemical onto an article. These processes have many uses in a wide range of industries, notably the automotive, plumbing and food packaging industries. Other industries may also utilise these processes to produce goods which have a chemical coating, in which an article may or may not be pre-treated by a plasma field prior to deposition of a chemical or other element or compound. However, there are a number of problems associated with the above processes in relation to deposition onto textiles.

A PVD process typically uses a PVD source material for deposition onto an article. In a PVD or PEPVD processes, PVD source material is evaporated via evaporation processes and the evaporated material will then condense on the article (evaporation PVD) to create the desired deposition, or a sputtering process will displace a source material to be deposited and condense on an article (sputtering PVD). For PVD processing, there are no chemical reactions that take place in the entire process, unlike CVD processes. As there are no chemical reactions, the purity of the source material may be required to be of a high purity, which may limit the conditions in which the PVD can occur.

Most articles receiving a deposition are generally polymer films or metals which are used for food stuffs, industrial components or commonly automotive components. Other uses for PVD may also be apparent. However, there are a number of problems associated with using PVD processes with regards to articles which have a high moisture content (greater than 1% to 2% by wt or volume, with some articles having 10% to 20% moisture content by wt or volume). Notably, substrates, such as woven or non-woven textiles, with high moisture content may not be suitable for PVD, PEPVD, CVD or PECVD processes as moisture the moisture content from the substrate or article may cause outgassing issues and pressure increases during processing which can ruin said article or substrate.

Known systems for PVD and PEPVD processing of a film substrate use a vacuum chamber and an evaporator apparatus to convert a solid source material into a vapour. The vacuum chamber may take on average between 30 minutes to 2 hours to be reduced to a desired internal pressure before processing can begin. However, often there are complications with regards to the moisture content of a substrate increasing internal chamber pressures which can result in the termination of processing and re-pressurisation of the chamber and therefore the chamber will need to be re-pressurised as well as having the risk that the substrate is no longer suitable for an end purpose. This can be costly, not only in relation to time and energy required, but also in relation to potential damage to substrates and other materials used in the system.

Even if processes are sufficient, substrates with high moisture contents may form inferior bonding with the deposition layer from the PVD process which may be a result of outgassing of the substrate. Other issues include visible “burns” (blacked or browned regions of deposition) or undesired oxidation of metals deposited onto the substrate. Uneven application of the PVD source material may also result from moisture within the substrate being gasified during the application of the PVD source material. In addition, impurities from the moisture may interact with the PVD source being deposited which may also cause poor bonding of the deposition layer or other issues with application of the PVD source.

Due to these issues, current systems are primarily used only for materials which have a relatively low moisture content (around 0.5% by wt or by volume) when placed into a PVD or CVD processing system. Therefore, current systems cannot support PVD or CVD processing for materials with a relatively high moisture content.

Any discussion of the prior art throughout the specification should in no way be considered as an admission that such prior art is widely known or forms part of common general knowledge in the field.

### SUMMARY

### Problems to be Solved

It may be advantageous to provide for a PVD system which can process materials with a high natural moisture content, relative to polymers.

It may be advantageous to provide for a system which can reduce the moisture content of a substrate or textile to for PVD processing.

It may be advantageous to provide for a moisture control device which can house a textile or substrate.

It may be advantageous to provide for a system which may degas a substrate and apply a PVD treatment.

It may be advantageous to provide for a system which may apply a PVD treatment to a substrate in a reduced time, compared to conventional methods.

It may be advantageous to provide for a system which may more efficiently degas a porous substrate.

It may be advantageous to provide for a device which can limit moisture content of a textile.

It is an object of the present invention to overcome or ameliorate at least one of the disadvantages of the prior art, or to provide a useful alternative.

### Means for Solving the Problem

A first aspect of the present invention may relate to a system for treating a substrate. The system comprising an unwinder adapted to receive and unwind a roll of substrate. A rewinder adapted to rewind the substrate from the unwinder. A physical vapour deposition (PVD) apparatus. A vacuum chamber in which the unwinder, PVD apparatus and rewinder are disposed; and wherein a coating drum of the PVD apparatus has a temperature of between 0° C. and 10° C., and is adapted to increase a desorption rate of the substrate.

Preferably, the textile may be unwound from the unwinder and wound at the rewinder, and unwound at the rewinder and wound at the unwinder. Preferably, the vacuum chamber comprises a winding chamber with a first pressure, and a PVD chamber with a second pressure. Preferably, the unwinder may also a further rewinder. Preferably, the rewinder may be a further unwinder. Preferably, the system comprises at least one plasma treatment module positioned adapted to generate a plasma. Preferably, the temperature of the drum may dynamically adjustable. Preferably, the system may be adapted to at least partly degas the substrate by exposing the substrate to a heated boat of the PVD apparatus. Preferably, the system further comprises a measuring roller. Preferably, the system further comprises a thickness measurement unit. Preferably, the system may pass the substrate between the unwinder and winder a plurality of times, while maintaining a vacuum in the vacuum chamber. Preferably, a first feeder is provided at the unwinder and a second feeder may be provided at the rewinder, each feeder being adapted to retain a portion of the substrate to reverse the direction of treatment of the substrate. Preferably, comprising a cooling system for capturing degassed contaminants. Preferably, the system may be connected to a vacuum storage which may store at least a portion of the vacuum from the vacuum chamber.

In another aspect of the present invention, there may be provided a method of degassing and applying a PVD treatment to a substrate using a system, the method comprising a degassing stage and a physical vapour deposition (PVD) stage. The degassing stage comprising the steps of; mounting a roll of substrate on an unwinder in a vacuum chamber; sealing the chamber and removing atmosphere from the vacuum chamber to a predetermined pressure; heating a coating drum of a physical vapour deposition (PVD) apparatus to 10° C. and activating a heating boat; passing the roll of substrate through the system such that the substrate may be heated by the coating drum and heating boat to degas the substrate; and rewinding the substrate after heating. The PVD stage comprising the steps of; unwinding the substrate and passing the substrate back through the system and evaporating a PVD source material to cause a deposition of the PVD source material on the substrate; and rewinding the substrate into a roll.

Preferably, the substrate may be passed through a pre-treatment module before being deposited with a PVD source in the PVD stage. Preferably, pressure in the system may be reduced for the PVD stage. Preferably, the method further comprises measuring the thickness of the deposition. Preferably, the method further comprises the step of passing the substrate through a post-treatment module to provide a finish to the deposition on the substrate. Preferably, the system may be adapted to perform two degassing stages.

In the context of the present invention, the words “comprise”, “comprising” and the like are to be construed in their inclusive, as opposed to their exclusive, sense, that is in the sense of “including, but not limited to”.

The invention is to be interpreted with reference to the at least one of the technical problems described or affiliated with the background art. The present aims to solve or ameliorate at least one of the technical problems and this may result in one or more advantageous effects as defined by this specification and described in detail with reference to the preferred embodiments of the present invention.

### BRIEF DESCRIPTION OF THE FIGURES

FIG. 1 illustrates a sectional view of an embodiment of a PVD processing system;

FIG. 2 illustrates a perspective view of an embodiment of a system for treating textiles;

FIG. 3 illustrates a flow chart of a two stage process for treating a textile in a system;

FIG. 4 illustrates a further embodiment of a system in a further chamber is disposed between the winding chamber and the PVD chamber;

FIG. 5 illustrates an embodiment of a trolley with a flexible bag mounted therein for enclosing a textile;

FIG. 6 illustrates an embodiment of a textile trolley with a closable cover adapted to reduce moisture ingress;

FIG. 7 illustrates a perspective view of an embodiment of a cradle with a roll mounted thereon;

FIG. 8 illustrates a perspective view of an embodiment of a straight arm cradle;

FIG. 9 illustrates an embodiment of a cradle adapted to be moved by a forklift;

FIGS. 10A-10D illustrate an embodiment of a method for mounting a roll in a sealable bag system;

FIG. 11 illustrates an embodiment of a longitudinal bag in which a roll can be retained; and

FIG. 12 illustrates an embodiment of a front view of a bag system being mounted onto a roll to be sealed inside.

### DESCRIPTION OF THE INVENTION

Preferred embodiments of the invention will now be described with reference to the accompanying drawings and non-limiting examples.

The present invention may be directed towards systems 10 and processes to control or reduce the moisture content of a textile for physical vapour deposition (PVD) and/or chemical vapour deposition (CVD) processing and improving the application of said PVD or CVD processes. Notably, bonding strength between the deposition and the treated substrate or consistency and quality of the coating may also be improved and result in a superior product.

The systems as described herein may have primary utility as roll-to-roll systems, although continuous systems are also described herein. Roll-to-roll systems may also be referred to as batch systems, and each roll may form an individual “batch”.

The system 10 may be suitable for processing a textile or other porous or non-porous substrate. While the system 10 may be used for any desired PVD and/or CVD processing, the system 10 described herein will make specific reference to aluminium (aluminum) PVD processing, although any desired process may be used and any deposition source material may be used for coating or treating a substrate. For example, silver, gold, copper or titanium or alloys thereof may also be suitable PVD source materials.

Substrates may include any sheet, textile, or flexible planar material which may be treated with PVD and/or CVD processing. Herein, specific reference in this specification will be made to textiles being treated by the system 10, however it will be appreciated that the term “textile” may be replaced with the term “substrate” as any desired substrate may utilise the benefits of the system 10 of the present disclosure. The term “substrate” may include textiles, films or any other planar articles.

Suitable textiles to be treated by the system may include at least one of; nylon, polyamide, rayon, polyester, PP, PET, PE, aramid, acrylic, acrylate, paper, wool, silk, cotton, linen, woven textiles, non-woven textiles, braided textiles, insulation materials, synthetic materials, natural materials, organic materials or any other material which may be suitable for use in a garment. It will be appreciated that a textile is a substrate formed with yarns, filaments, strands or fibres which are interconnected in a regular or ordered manner (woven textiles) or bonded together in the case of non-woven textiles. These textiles have pores or gaps between fibres, yarns, filaments, or strands, which makes these textiles breathable which is a highly desired property for garments. However, gaps and pores also allow moisture within the textile structure and therefore have a relatively high moisture content relative to films. These gaps also increase the overall surface area of a side of the textile and therefore make typical degassing processes more difficult and time consuming. As such, the system and method as discussed herein may be used to increase the speed of degassing of a substrate and improve PVD bonding. It will be appreciated that while PET (polyethylene terephthalate) and PP (polypropylene) films may be readily treated by PVD processing by known techniques, textiles made from PET and PP are not readily treatable as the overall structure of the material is different. Notably, the yarns, filaments, weave, or non-woven structures have an overall substantially higher surface area than conventional PP or PET films, as the films are non-permeable films or non-porous films. As such, moisture may more easily move into the textile gaps between yarns and/or filaments and be difficult to remove by conventional drying processes due to the relatively higher surface area of the textile. It will be appreciated that the energy required to remove liquids (moisture), such as water, from a surface is relatively high, and therefore a substrate or textile with a higher surface area which has been exposed to a liquid (moisture) will require a greater energy input to remove said liquid. As non-porous films generally have a smaller surface area compared with woven and non-woven textiles (particularly if the wovens and non-wovens comprise fibres) conventional methods for moisture removal from films are generally not sufficient for removing the moisture from textiles.

Known systems for PVD of aluminium are generally only used to treat paper and polymer films. These materials are generally desirable for foodstuffs and food products and have a generally low ambient moisture content of around 0.5%, depending on humidity and storage location of the substrate. These products can be treated by known PVD methods to obtain a product in which at least one surface of the substrate is coved with a PVD source material, such as aluminium. However, there are instances where these types of materials may be dried prior to PVD processing to remove excess moisture in the substrate.

The structural nature of films of PP, PET or paper are generally non-porous and therefore moisture on or within the substrates are readily removed (degassed). However, in contrast with substrates, such as textiles to make garments, this is not the case and higher surface areas are observed in these substrates which make typical drying processes ineffective, too costly or too time consuming to achieve a lower moisture content.

Degassing of textiles is understood by those in the art as the deliberate removal of moisture content from the textile until a generally uniform weight is observed or a desired moisture content is observed. Outgassing is the spontaneous evolution of gas from solid or liquid and the diffusion of a gas to the surface of an object where it desorbs. Porous materials outgas by surface or volume migration through the pores and along the pore surfaces to the surface, where they desorb. Outgassing is typically a major source of gaseous contamination in a vacuum system. Desorption is the release of adsorbed chemical species from the surface of a solid or liquid.

Degassing of textiles is primarily used to remove moisture from a textile such that deposition processes are more effective. While this is typically not a concern for film substrates, such as PET films or PP films with a general moisture content of around 0.5% (by wt), textiles for use in clothing or garments will generally have a moisture content of between 15% to 5% (by wt), such as nylon having a moisture content of around 6%. Further, even for materials such as PP or PET textiles the pores or gaps in the substrate structure leads to a higher overall surface area for liquids to adhere to, which can lead to significant deposition issues during PVD processing. Such deposition issues may include; uneven deposition appearance, “burn marks”, excessive or undesirable oxidation, uniform application of depositions, system shutoff, pressure spikes, bonding issues or other defects.

Defects may also originate in relation to the general cleanliness of a substrate which may occur after processing in the period of time before a PVD or CVD process is completed. As such, further cleaning or sterilisation of the substrate may be costly and time consuming to get the substrate to a state in which a suitable PVD or CVD process can be completed.

Degassing may also have the additional benefit of removing oils and other dyeing and/or extrusion contaminants from the textile which may improve the adhesion of deposition source materials.

The system, devices, and processes of the present disclosure may ameliorate at least some of the known problems associated with PVD processing of a porous substrate or a substrate with a relatively high moisture content. The devices and/or system may also provide for moisture absorption barriers for substrates while substrates are in storage or in transit, which may also improve upon known processes and may also maintain a relatively cleaner substrate to undergo PVD or CVD processing.

Gases and vapours determine the lowest pressure, or “base pressure”, that can be reached in a given time, and the gas and vapour species in the system 10 at any time, and how fast the chamber pressure rises after the pumping is stopped. Further, water adsorbed on surfaces of textiles is rapidly desorbed when the surface is heated or is in contact with plasma which again can cause pressure increases within chambers 128, 110. As such, moisture content within a textile 1 (substrate) being processed will be desorbed rapidly when PVD source material comes into contact with the substrate, or is in close proximity with the substrate. Further, the heat of the boat may also cause desorption or rapid desorption of moisture within the textile 1 due to the heat radiating from the evaporator apparatus 116 towards the textile 1.

Water vapour from outgassing and desorption is often the most significant contaminant species in typical deposition vacuums. As such, it is beneficial to remove as much moisture as possible (degassing) before PVD processing. However, as most substrates will have a natural moisture content, this natural moisture content may not be lowered to a desirable level by known degassing methods or systems, and therefore would typically be unsuitable for PVD processing and sputtering processing may instead be required. However, as PVD provides a relatively thinner coating of source material, sputtering processes are typically undesired for some applications. Notably, as sputtering processes are generally magnitudes slower than evaporation PVD processes and sputtering also deposits atoms which are of a higher energy relative to an evaporation process, which heats the substrate more and potentially causing further outgassing. For example, a sputtering process will generally allow a treatment speed of between 0.1 m/s to 0.5 m/s, whereas PVD evaporation processing may allow for treatment speeds of 1 m/s to 10 m/s depending on desired thickness of deposition, therefore increasing production speeds and efficiency. While some sputtering methods may also have a high deposition rate, near to that of evaporation methods, high sputtering rates are generally only achieved when the substrate is a metal, and therefore treating textiles cannot achieve this high sputtering rate. In addition, energy and sputtering source materials are consumed at a higher rate to process a roll, compared to that of the PVD process of the present disclosure.

It has been observed that the resistance to evaporative transfer (RET) of a textile before PVD coating and after PVD coating is substantially the same, if not the same. This is a significant advantage over metal films which may be adhered to a textile, rather than textiles 1 receiving a deposition. Further PVD evaporation processes may have a negligible impact on the moisture vapour transfer of the textile, which is a significant advantage over known methods.

One method of reducing moisture content of a substrate may be to increase the surface temperature of the substrate to increase the desorption rate. Desorption rates are generally sensitive to the surface conditions, coverage and surface area. Plasma desorption may be used to hasten desorption of water vapour on vacuum surfaces, and plasma pre-treatment module 104 may also assist to reduce the moisture content of a substrate.

Optionally, to reduce moisture content, substrates may be vacuum baked prior to being placed into the system 10 to reduce the moisture content as much as possible, however, even with baking processes which are high energy consumption the time between exiting the baking process and being loaded into the system can increase the moisture content to an undesired level, which can again cause pressure increases in the PVD chamber, and inferior bonding of the PVD source material.

Apparent outgassing can result from the PVD processing. For example, the evaporation of aluminium in a system containing water vapour can produce hydrogen “outgassing” as the aluminium reacts with adsorbed water vapour to release hydrogen.

Outdiffusion is when the material that diffuses from the substrate and does not vaporize but remains on the surface. These surface species then have a vapour pressure that contributes to the gaseous species. Outdiffusion can cause pressure increases within the system 10 in operation.

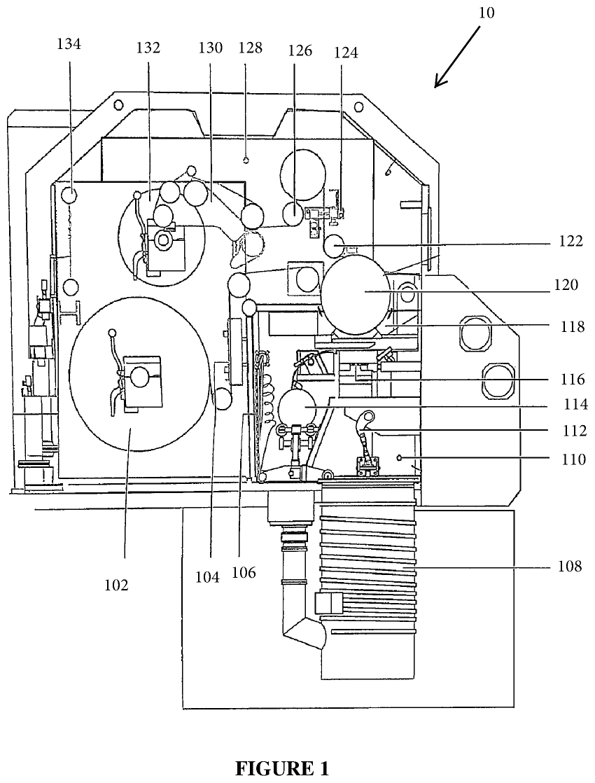

Referring to FIG. 1, there is illustrated an embodiment of a deposition system 10 which is suitable for PVD processing a textile. The system 10 as shown is a roll-to-roll system 10 which comprises; an unwinder 102, a pre-treatment module 104, a cooling system 106, a pump 108, a PVD chamber 110, a drive for vacuum valve 112, a wire coil 114, an evaporator apparatus 116, a coating window 118, coating drum 120, measuring roller 122, layer thickness measurement unit 124, further measuring roller 126, winding chamber 128, swivel arm 130, rewinder 132 and further cooling system 134.

While the system 10 as shown includes a cooling system 106 and a further cooling system 134, it will be appreciated that these features may be optional, or may be placed at different locations that that shown. In addition, further cooling systems or moisture traps can be disposed throughout the system 10. Similarly, the system may or may not be fitted with the pre-treatment module 104, or further treatment modules similar to that of pre-treatment module 104 may be provided in other sections of the system 10.

Typically to use the system 10, a textile 1 will be provided to the system as a roll 2 which can be mounted on an arm 103 of the unwinder 102 in the winding chamber 128. The arm 103 of the unwinder 102 is used to support the substrate 1 while being processed. The arm 103 may be free to rotate as the system 10 processes the textile, or may be fixed such that a tubular core of the textile roll 2 can rotate about the arm of the unwinder 102. Optionally, the unwinder 102 is provided with a motor which can rotate the roll 2 at a desired speed to allow for improved processing speeds and/or impart a desired tension to the textile 1 prior to treatment.

Once the textile 1 is loaded within the system 10, the system is sealed and a fluid gas tight seal is formed between ambient atmosphere and the winding chamber 128 and the PVD chamber 110. The drive for the vacuum valve can be activated and the chambers can be depressurised by the pump 108. The overall desired vacuum pressures within the system 10 will depend on the textile 1 being processed and the PVD or CVD source material. Preferably, the winding chamber 128 has a pressure of around 1×10⁻² to 1×10⁻³ mbar and the PVD chamber has a pressure of around 1×10⁻⁴ to 1×10⁻⁵ mbar during PVD processing. When the system is being used to degas a substrate, the winding chamber 128 may have a pressure of around 1×10⁻¹ to 1×10⁻³ mbar and the PVD chamber has a pressure of around 4×10⁻³ to 1×10⁻⁵ mbar. Generally, it will take a TopMet™ 1650 PVD system around 50 minutes to 90 minutes to achieve the desired PVD processing vacuum pressures. Other PVD systems will also take similar vacuuming times. Once desired internal pressures are reached, processing of the textile 1 can begin.

A lead portion of the textile 1 can be mounted in a feeder which can be used to feed the textile 1 to the pre-treatment module 104. The pre-treatment module 104 is preferably a plasma treatment module 104 which can be used to activate the surface of and/or sterilise the surface of the textile 1. While the illustrated embodiment shown is a single side pre-treatment module 104, said module 104 may be a double sided treatment module 104 which can activate and/or treat both surfaces of the textile 1. This may be advantageous as the pre-treatment module 104 may be used for degassing a textile to reduce the overall moisture content of the textile 1. A coolant system (not shown) for the pre-treatment module 104 may also be provided such that electrodes used to generate the plasma do not overheat within the winding chamber 128. The pre-treatment module 104 may be any desired device which can generate a plasma or provide a sterilising effect which can be used to treat at least one surface of a textile 1. Other pre-treatments may also be applied to the substrate before PVD processing using the system 10. Other pre-treatments may be primarily used for cleaning, sterilisation and/or bonding enhancement in advance of PVD processing.

As a textile 1 is being pre-treated by the pre-treatment module 104, the textile 1 will typically release residual gas (such as water vapour) from the textile 1 structure which can be captured by a cooling system, such as a cryo-condensation trap or other device. The cooling system preferably is maintained at a temperature of, preferably less than −20° C., or more preferably less than −40° C., or even more preferably less than −100° C., or less than −150° C. Having a temperature at −100° C. or less can freeze contaminant fluids, such as water, degassed from a textile 1 while maintaining a low vapour pressure within the chamber. Further, the cooling system 106 may also be used to freeze contaminants within the textile 1 such that outgassing of contaminant fluids is reduced during PVD processing. The cooling system 106 may be used to capture moisture in the chamber 128 by condensing and freezing any moisture vapour released by the textile 1 during pre-treatment or other degassing methods. In a preferred method of using the system, as will be described below, the system 10 is used to perform a two stage processing of a substrate, in which the first stage is a degassing stage and the second stage is a PVD processing stage.

After passing near to the cooling system 106 to capture said degassed contaminants, the system 10 feeds the textile 1 through to coating drum 120, to then be passed into PVD chamber 110. The coating drum 120 may be situated at the interface between the PVD chamber 110 and the winding chamber 128. Each of the chambers 128, 110 may have a respective pressure and the interface between the chambers allows enough clearance for passing a textile through into the PVD chamber 110 without pressures being significantly lost (bleeding or leaking of pressure from the PVD chamber to the winding chamber 128) at the interface. Differentially pumped roller valves or differentially pumped slit valves may be disposed at the interface to reduce undesired pressure changes within the chambers 110, 128. The PVD chamber 110 preferably has a lower pressure (higher vacuum) than that of the winding chamber 128. The pressure within the PVD chamber 110 is essential to provide the correct conditions for PVD to occur and therefore a maximum pressure threshold is established to terminate processing if it is exceeded. Pressure thresholds are of use particularly in the case of aluminium PVD processing which requires a purity of aluminium of approximately 99.80% at the correct pressure conditions of PVD processing will fail or produce a deposition which is defective. Other purities may also be used, but it is preferred that a purity of the aluminium is at least 95% to be used with the system 10. Other suitable PVD source materials may include at least one of; gold, silver, copper, and titanium.

A list of suitable PVD source materials may include at least one of the following: Aluminum, Aluminum Copper, Aluminum Copper Tungsten, Aluminum Nitride, Aluminum Oxide, Aluminum Silicon, Antimony, Barium, Barium Ferrite, Barium Fluoride, Barium Strontium Titanate, Barium Titanate, Barium Oxide, Beryllium, Bismuth, Bismuth Lanthanum Titanium, Bismuth Strontium Calcium, Bismuth Strontium Titanate, Bismuth Titanium Oxide, Bismuth Trioxide, Boron, Boron Carbide, Boron Nitride, Cadmium Fluoride, Cadmium Oxide, Cadmium Selenide, Cadmium Sulfide, Cadmium Telluride, Calcium Fluoride, Calcium Oxide, Calcium Silicate, Calcium Titanate, Carbon (Graphite), Carbon Steel, Cerium, Cerium Oxide, Chromium, Chromium Boride, Chromium Oxide, Chromium Silicide, Cobalt, Cobalt Chromium, Cobalt Oxide, Cobalt Silicide, Cobalt Zirconium, Copper, Copper Sulfide, Copper Oxide, Dysprosium, Erbium, Europium, Gallium, Gallium Arsenide, Gallium Oxide, Gadolinium, Germanium, Germanium Nitride, Germanium Oxide, Gold, Gold Germanium, Gold Palladium, Gold Tin, Gold Zinc, Hafnium, Hafnium Carbide, Hafnium Nitride, Hafnium Oxide, Holmium, Inconel, Indium, Indium Oxide, Indium Tin Oxide, Iridium, Iron, Iron Oxide, Lead, Lanthanum, Lanthanum Aluminate, Lanthanum Boride, Lanthanum Oxide, Lanthanum Strontium Cobalt Oxide, Lanthanum Manganese Oxide, Lead Oxide, Lead Titanate, Lead Zirconium Titanate Oxide, Lithium, Lithium Carbonate, Lithium Cobalt Oxide, Lithium Niobate, Lithium Phosphate, Lithium Tantalate, Magnesium, Magnesium Fluoride, Magnesium Monoxide, Magnesium Oxide, Manganese, Molybdenum, Molybdenum Disulfide, Molybdenum Oxide, Molybdenum Selenide, Molybdenum Silicide, Molybdenum Sulfide, Neodymium, Neodymium Gallium Oxide, Neodymium Iron Boride, Nickel, Nickel Chromium, Nickel Cobalt, Nickel Oxide, Nickel Silicide, Nickel Vanadium, Niobium, Niobium Oxide, Palladium, Platinum, Praseodymium, Pryolytic Boron Nitride, Rhenium, Rhodium, Ruthenium, Samarium, Samarium Cobalt, Scandium, Scandium Oxide, Selenium, Silicon, Silicon Carbide, Silicon Dioxide, Silicon Monoxide, Silicon Nitride, Silver, Silver Oxide, Strontium Bismuth Niobium Oxide, Strontium Bismuth Tantalum Niobium, Strontium-doped Lanthanum, Strontium Oxide, Strontium Titanate, Tantalum, Tantalum Carbide, Tantalum Nitride, Tantalum Oxide, Tantalum Silicide, Tantalum Sulfide, Tellurium, Terbium, Terbium Iron, Thallium, Thallium Oxide, Thorium Fluoride, Thorium Oxide, Tin, Tin Oxide, Titanium, Titanium Boride, Titanium Carbide, Titanium Nitride, Titanium Oxide, Titanium Silicide, Titanium Sulfide, Tungsten, Tungsten Silicide, Tungsten Sulfide, Tungsten Titanium, Vanadium, Vanadium Pent Oxide, Yttrium, Yttrium Barium Copper Oxide, Yttrium Oxide, Zinc, Zinc Oxide, Zinc Selenide, Zinc Sulfide, Zirconium, Zirconium Nitride, Zirconium Oxide, Zirconium Silicate, Zirconium Oxide Yttrium Oxide.

Optionally, the pump 108 can be used to remove atmosphere from both the winding chamber 128 and the PVD chamber 110. Alternatively, separate pumps may be provided to remove pressures from each of the chambers 128, 110. The pump 108 can also be used to gradually restore atmosphere to at least one of the PVD chamber 110 and the winding chamber 128. A vacuum can be defined as a volume that contains fewer gaseous molecules than the ambient environment when both contain the same gaseous species and are at the same temperature.

The coating drum 120 transports the textile 1 through the PVD chamber 110 at a speed of between 30 m/min to 200 m/min depending on the desired deposition thickness, but is preferably around 120 m/minute. It will be appreciated that the system may have the ability to process textiles 1 at a speed of up to 300 m/min The coating drum 120 of the system of the present invention can be temperature controlled to have a temperature between −1° C. to −20° C. to reduce outgassing of a substrate (textile 1) undergoing a PVD process and also and assist with condensing a vapour onto a substrate (textile 1), and thereby reducing pressure variances within the PVD chamber 110. Reducing outgassing by lowering the coating drum 120 temperature during PVD coating processes is not known in the art, and provides a significant advantage. In one embodiment, the temperature of the coating drum 120 is cooled to between −5° C. to −10° C.

An evaporator apparatus 116 is provided in the PVD chamber 110 which is used to evaporate a PVD source material, which is typically provided by wire 114. The evaporator apparatus 116 comprises a receptacle or ‘boat’ is used to evaporate the PVD source material 114 at a desired time. The boat can be heated to a predetermined temperature sufficient to evaporate the PVD source material after the source material comes into contact with the boat. Further, the boat may be activated to generate heat without a source material being provided to evaporate. Preferably the system is adapted to evaporate a PVD source material when a substrate enters into the PVD chamber.

When the PVD source is evaporated, the vapour moves in a predetermined direction, which is typically upward, and the substrate 1 can be coated by the vapour. This allows for a relatively thin coating of aluminium to be deposited onto the textile 1 being treated. The coating of aluminium condensed and deposited onto the textile 1 is preferably in the range of 10 nm to 200 nm, or between 30 nm to 100 nm, or between 50 nm to 100 nm, or any desired thickness within the range. Preferably, the aluminium coating thickness is 100 nm or less, or 70 nm or less, or 50 nm or less, or 30 nm or less. PVD processing may cause the moisture contained within the textile 1 may be outgassed which increases the internal pressures within the PVD chamber 110. Outgassing may be caused by the heat source for evaporating a source material, and/or may be caused when vapours are near to the substrate or when vapours are deposited and/or condense onto the textile 1. If the pressures are too high, the system 10 will shutoff and the PVD processing will cease.

As mentioned above, outgassing occurs when the evaporated PVD source material comes near to, or in contact with, the substrate (textile 1) causing moisture within the substrate to transition to a gaseous state, or when the substrate (textile 1) is exposed to heat radiating from the heat source for evaporating a source material. Outgassing causes rapid pressure changes within the PVD chamber 110 as liquid or solid contaminants (typically water) rapidly change state to gaseous form and move from the pores within the structure of the substrate 1 and come to the surface of the textile 1. The outgassing contaminants may also be released into the PVD chamber 110 and are generally a source for triggering a shutoff of the system if pressures exceed thresholds. As gas is released into the chamber, the internal pressures increases. As outgassing introduces additional gas into the PVD chamber so rapidly, the pump 108 cannot remove additional gas within the system before pressure threshold(s) are exceeded. In view of the above, the system 10 is preferably adapted to minimise pressure fluctuations within the system 10 and reduce outgassing of the textile 1 being processed. Further, as outgassed contaminants are present at the surface of the textile 1, this may form a physical barrier which prevents aluminium or another source material from forming a desired bond with the textile 1.

If the pressure in the PVD chamber 110 does not exceed a shutoff threshold, the pressure observed will begin to decrease to a desired pressure after the initial increase in pressure from the degassed contaminants has been observed. As the pressure decreases, it will be observed that pressures will level out and remain constant as degassed contaminants entering into the system will generally remain constant and the pump will be active to remove the additional contaminants in the PVD chamber 110 at a rate which can achieve the desired pressure. In another embodiment, the system is adapted to slowly process a roll such that when pressure increases are observed in the PVD chamber the pump may remove these additional contaminants in an attempt to lower the pressure, and the speed of the substrate being fed into the PVD chamber may increase at a rate which the pump can effectively remove contaminants from the PVD chamber until a maximum desired speed is reached. When the desired speed is reached, the pressure in the PVD chamber may remain constant.

Pressure increases above predetermined thresholds may cause shutoff of the system 10 and/or repressurisation of the system 10. As such, the system 10 will need to be reset and subsequent depressurisation to continue processing of the textile 1 which can be costly and time consuming. Further, as the system may only allow for around 5000 yards of textile 1 to be processed at a single time, the delays involved with a shutoff are unjustifiable.

Further, while it may seem obvious to increase the thresholds of pressures within the PVD chamber 110, increased thresholds are generally insufficient to allow for desirable PVD processing (certainly with respect to aluminium) as the increase in pressure is likely to cause errors in coating, undesired distributions of PVD source material, and unintentional sputtering of PVD source material for example.

A coating window limits or restricts the deposition area on the textile 1 as the coating drum 120 carries the textile 1 through the PVD chamber 110. In this way the textile deposition area can be controlled and the angle of deposition can also be controlled. It will be appreciated that the coating window 118 can also be decreased to minimise the amount of outgassing at one time and reduce PVD chamber pressures. However, having the PVD window of a relatively smaller size may also reduce the speed in PVD processing of a textile 1 can be achieved.

During PVD processing, after the textile 1 exists the PVD chamber 110, the textile 1 will have been deposited with a PVD source material. The textile 1 can then be passed via a measuring roller 122 which measures the length of textile processed and can determine the amount of textile 1 remaining on the roll. A layer thickness roller may also be provided to determine the thickness of the deposition on the textile 1.

A further measuring roller may also be provided which can confirm the length of textile which has passed through the system such that the system 10 does not prematurely finish processing the textile 1. The swivel arm 130 of the system is used to guide the textile 1 onto the roll and create the desired tension such that the textile is rolled with a desired tautness. Further, the swivel arm 130 can be used to control the winding direction such that a coating is either facing outwardly on the roll or inwardly. If the system 10 is adapted to allow the textile 1 to be passed from the winder 132 to the unwinder 102 and back again without re-pressurisation and subsequent unloading and reloading of the roll, a further swivel arm (not shown) may also be disposed near to the unwinder 102 to allow for the unwinder 102 to rewind the textile in a desired manner. Preferably, a moisture sensor is also disposed within the vacuum chamber 22, which is adapted to determine a moisture content of the textile 1 before PVD processing. If the moisture content is not at or below a desired moisture content, the system may use further degassing processes to further remove moisture from the textile 1. In one embodiment, an infrared moisture meter may be used, to determine moisture content.

A rewinder 132 is provided at the end of the processing line which is used to rewind the textile into a roll 2. The processing line starts at the unwinder 102, and ends at the rewinder 132, and includes the processes and treatments applied to a substrate/textile 1. Optionally, further cooling systems 134 can be provided which can be used to capture degassed contaminants within the system 10 and assist with maintaining a desired pressure within the winding chamber 128. Preferably, the inclusion of at least three cooling systems may be desirable for capture of degassed contaminants, particularly with respect to capture of degassed/outgassed contaminants from paper substrates.

Optionally, a further treatment module (not shown) can be disposed in the winding chamber 128 which can be used to treat a substrate. For example, a further plasma treatment module may be provided to activate a surface of the substrate, or treat the deposition to assist with bonding, or any other desired function. Treatment modules, such as plasma treatment modules, may also be used to assist with degassing the textile 1.

The tail end of the textile 1 may be retained in a feeder near to the rewinder 132 at the end of the system 10 such that the tail end becomes the leading end for a subsequent PVD processing stage. Alternatively, the substrate 1 is connected to a roll core 3 on both the unwinder 102 and rewinder 132, such that when the substrate 1 is exhausted from the roll 2 on the unwinder 102, the process may be reversed and the system 10 may pass the substrate back through the processing line to be treated by a further process (such as degassing, PVD or CVD processes), or passed back through the system to be rewound on the unwinder 102 and processed in a direction only from the unwinder 102 to the rewinder 132. Preferably, the system allows treatments to be performed in both directions, i.e. from the unwinder 102 to the rewinder 132, and from the rewinder 132 to the unwinder 102.

Processing substrates with higher volume of moisture in conventional systems may be impossible as depositions readily fail and system shutdowns occur due to outgassing and pressure increases. Further, the deposition quality is also impacted and severe aesthetic imperfections are likely to be generated, and poor bonding of the deposition layer is likely to be observed. Notably, this is due to moisture in the substrate being outgassed during the PVD process. In contrast, the system 10 of the present disclosure is adapted to apply a deposition to a substrate which has relatively higher ambient moisture content (greater than 0.5% by wt % and/or by volume %), or more generally a substrate which has a higher overall surface area compared to a film or other typical PVD coated substrate.

To treat textiles with PVD, it may be necessary to lower the outgassing rate of the textile 1. One method may include, lowering the coating drum temperature to a temperature lower than −1° C., preferably around −5° C. to −10° C., or more broadly in the range of −1° C. to −30° C. It will be appreciated that lower temperatures for the coating drum 120 may also be used, although lowering the drum temperature will also increase the power consumption of the system 10 with little benefit comparatively. However, lower temperatures may be desired if higher moisture contents are present, such as when treating wool or other similar textiles 1. Having the coating drum achieve and maintain this temperature allows for a constant PVD processing speed of around 1 m/s to 2 m/s or greater and reduces outgassing of the textile 1 to pressures which are lower than the maximum pressure threshold while also assisting with condensing the evaporated source material onto the textile 1. In one embodiment, the maximum pressure threshold is 2×10⁻² mbar. With a reduction of outgassing during processing, a superior bond may be formed between the PVD and the textile 1.

In contrast, during degassing the temperature of the coating drum 120 is preferably between 0° C. and 20° C. more preferably, the temperature of the coating drum 120 is in the range of 3° C. to 7° C., even more preferably, the temperature is 4° C. to 6° C.

It will be appreciated that higher degassing speeds may be achieved by increasing the drum 120 temperature during degassing. The temperature of the drum 120 can be dynamically adjusted by the system in response to sensors detecting at least one of; a thickness of the deposition, a temperature of the textile, outgassing pressures or measurements by the measurement roller. It will be appreciated that the system 10 may also be adapted to increase pressure thresholds or ignore pressure thresholds when the system 10 is being used for degassing. In this way, a desired speed and degassing rate may be achieved which can be beneficial for textiles 1 or substrates with a high moisture content, such as wool, nylon or other similar garment materials. Dynamically adjusting the temperature of the drum can assist with controlling outgassing of the textile, and improve condensation and deposition of the source material.

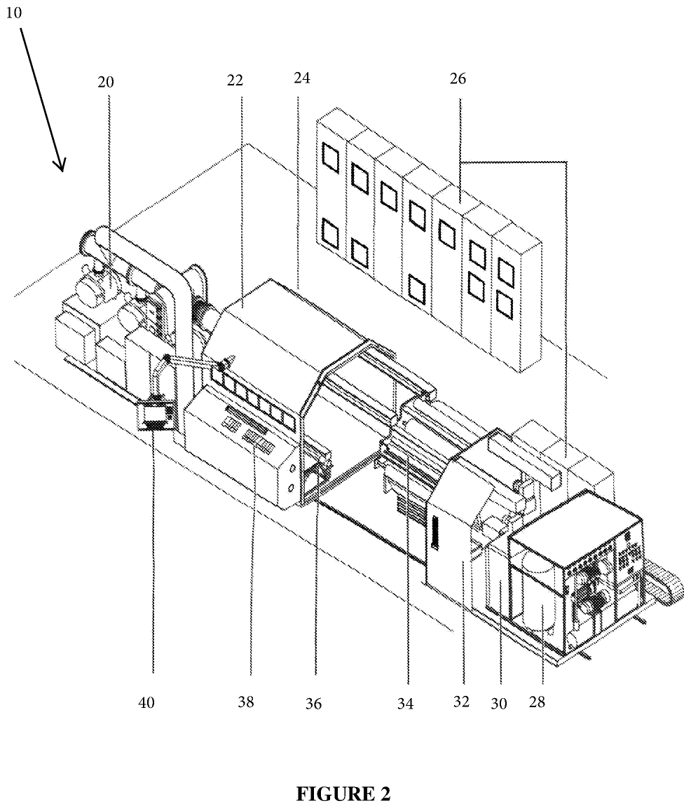

A perspective view of an embodiment of the system 10 is shown in FIG. 2. As illustrated there is a vacuum pumping station 20, vacuum chamber 22, media supply 24, switching cabinets 26, cooling and heating equipment 28, refrigerator 30, travelling part 32, winding system and pre-treatment station 34, evaporator station 36, operating panels 38, and graphic user interface with monitor 40.

The vacuum pumping station 20 houses the pump 108 which can be used to remove atmosphere from the chambers 110, 128. The winding chamber 128 and the PVD chamber may be collectively referred to as the vacuum chamber 22. In an unillustrated embodiment, the PVD chamber and the winding chamber 128 may be the same chamber and all processing actions occur within the same chamber.

The media supply 24 provides the necessary materials for PVD processing, such as chemicals for CVD processing, or source materials for PVD processing, or providing a plasma gas to the pre-treatment module 104, or treatment modules. Switching cabinets 26 house electronics and computing systems to monitor and control the system 10. The cooling and heating equipment 28 used for regulating the temperatures of components within the system 10, such as the pre-treatment device 104, cooling system 106 and the coating drum 120. A refrigerator 30 may be used to store coolant for components of the system 10.

As the system is required to be sealed, the vacuum chamber 22 and the winding and pre-treatment station 34 may be relatively displaceable to allow for placement of a substrate within the system 10, and also maintain the vacuum chamber 22 in a secured position. An evaporator station is housed within the vacuum chamber 22. Operating panels 38 and monitor 40 may be used to provide inputs to the system and may be adapted for a user to monitor the treatment processes.

The system 10 may be adapted to run any predetermined software which may control functions of the system 10. For example, the system 10 may be adapted to use the two stage processing method of the present disclosure.

Pressure thresholds may be modified via the monitor for different treatment processes and temperatures of components of the system 10 may also be modified for desired treatments. In one embodiment, pressure thresholds may be turned off (or raised) during degassing, and may allow for higher temperatures of the coating drum and/or the boat to heat a textile to increase the desorption rate. In yet another embodiment, the degassing process can be run while the system is being vacuumed which may save on overall processing time. Other modifications may include altering the flow rate of plasma gases to the pre-treatment module, temperature of cooling systems, coating drum temperatures, introducing a PVD material source to be evaporated, and speeds of processing.

It will be appreciated that the system 10 as shown in FIG. 2 is exemplary only and other configurations for the system 10 may also be used. In addition, further pumps, controllers, computer systems, chambers and treatment stations may be provided.

In one embodiment, the system 10 may be adapted to dynamically alter the temperature of the coating drum 120 such that the internal pressures within the system 10 are maintained below a predetermined pressure without system shutting down. To achieve this, the system 10 may be provided with an intermediate pressure threshold which is lower than the shutoff pressure threshold. If the intermediate pressure threshold is exceeded it may be used as a trigger to lower the temperature of the coating drum 120 such that the internal pressures are lowered to ensure the shutoff pressure threshold is not exceeded. The speed of the textile 1 to be coated may also be reduced in response to pressure increases from outgassing of the textile. This may allow for improved processing as the system is less likely to shutoff or cease PVD treatment processing.

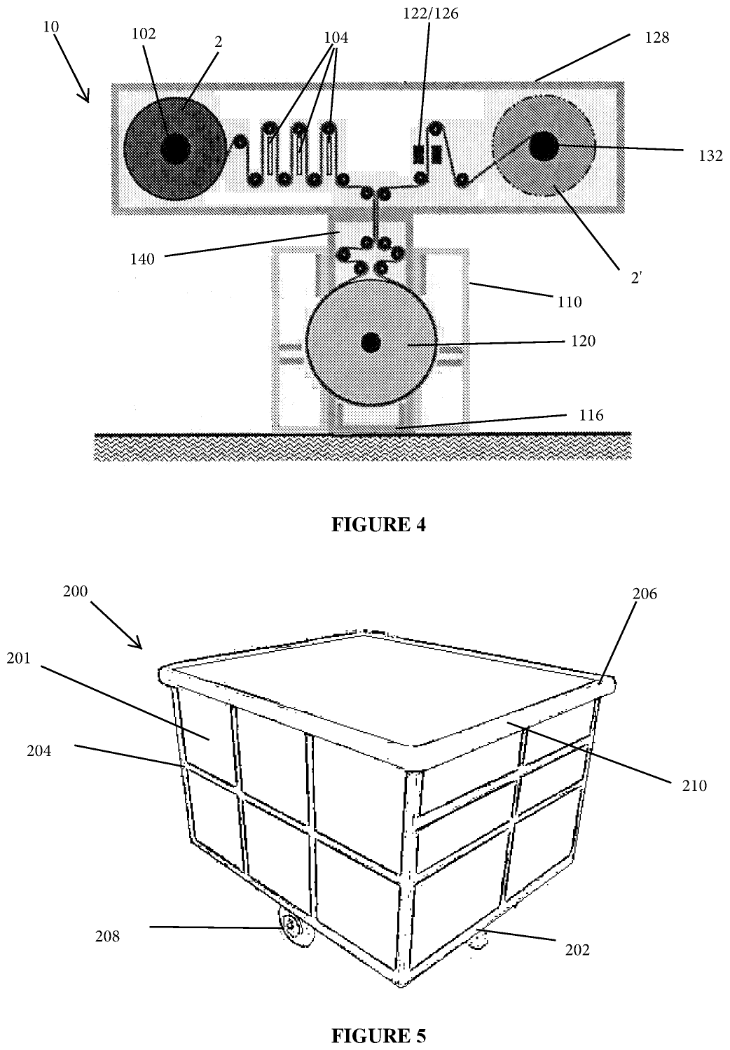

In another embodiment as seen in FIG. 4, a heating chamber 140 is provided before the PVD chamber 110 which allows for textiles 1 to be heated while the PVD chamber 110 temperature and pressures remain relatively constant. The heating chamber 140 may encourage further degassing before PVD application which could potentially cause outgassing of the textile 1 and associated pressure increases. The heating chamber 140 may have a third pressure which can be controlled separately compared to the other two chambers 110, 128, and may allow for higher pressures therein. As pressures are varied between all chambers, each chamber interface is preferably fitted with valves or sealing means to prevent or reduce pressure bleeding between chambers. This may allow for a degassing of a textile 1 in the heating chamber which can reduce potential pressure increases (spikes) in the pressure within the deposition chamber 110. Optionally, at least one heat source may be included within the winding chamber to allow for degassing of a textile 1.

Using the above described systems 10 may provide for PVD treatment processes which are more efficient, more reliable, and also provides for a deposition which is relatively more abrasion resistant compared to that of other methods. The abrasion resistance is improved by the reduced moisture content at the time of deposition, in addition the activated surface may improve deposition bonding and provide for a superior abrasion resistance.

In an unillustrated embodiment, the system may be an air-to-air processing system wherein the substrate is in atmospheric conditions and passes into a PVD chamber 30 to be treated by the desired PVD processes. The PVD chamber may have differentially pumped roller valves or differentially pumped slit valves which allow the substrate to enter the PVD chamber to be treated and then exit to be wound on a winder. As discussed above, exposure to atmosphere is undesired as this is likely to increase the moisture content of a material. As such, the substrate may be provided to the PVD chamber directly from a baking processing system upstream from the PVD chamber such that the moisture content of the substrate is kept to a minimum. A system such as this may allow for larger volumes of substrates to be processed as continuous processing may be achieved.

Similar to chambered roll to roll systems, at least one plasma module may also be used to treat at least one surface of the substrate prior to PVD processing of the substrate. The plasma treatment module may be positioned adjacent to the valves which allow entry of the substrate into the PVD chamber, such that a surface of the textile to be deposited on can be cleaned, sterilised and/or activated prior to treatment.

Activation of the surface of the substrate to be treated may improve adhesion of the PVD source material to said substrate. Further, as the surface can be cleaned by the plasma, the surface is typically free from most or all potential contaminants which could impact PVD processing. If a plasma module is used, the plasma module may be an open atmosphere plasma module such as at atmospheric plasma glow module. Any plasma devices used for the treatment of the substrate prior to PVD processing may be contained within a chamber or have controlled local atmospheric conditions such that ionisation of atmospheric gases or polymerisation of monomers within atmospheric gases is reduced or eliminated.

The PVD evaporation processes of the system may be enhanced with the used of ion-beam assisted deposition (IBAD) techniques. These techniques may use concurrent ion bombardment with evaporation PVD methods to assist deposition on a substrate 1. IBAD systems may provide for independent control of parameters such as ion energy, temperature and arrival rate of source material during deposition. Further, built-in stain of the deposited source material may be reduced compared with evaporation or sputtering techniques alone. IBAD systems may also assist with controlling and altering the microstructure of the substrate. When the deposition reaction takes place on the hot substrate surface, the films can develop an internal tensile stress due to the mismatch in the coefficient of thermal expansion between the substrate and the film. Low-energy or high-energy ions can be used to bombard coatings and change the tensile stress into compressive stress. Ion bombardment also increases the density of the film, changes the grain size and modifies amorphous films to polycrystalline films. Preferably, low-energy ions are used to treat textiles 1.

In another embodiment, e-beam evaporation methods may be used to heat a source material to a desired temperature, rather than introducing a source material to a heated evaporation crucible or boat. This evaporation method may provide for a desired deposition rate for processing speeds of 1 m/s, or 2 m/s or 3 m/s, or 4 m/s, or 5 m/s or between 1 m/s to 10 m/s.

In yet a further embodiment, the system 10 may use a sputtering process in advance of a PVD evaporation process. In this way, a relatively thin sputtered layer can be deposited onto the substrate 1 and then evaporation PVD methods can be used to form a desired thickness of the substrate. Using both sputtering and evaporation PVD methods can be used for improved bonding, particularly if a substrate deposition surface is not activated prior to deposition. While sputtering depositions cannot be applied in desired thicknesses with a processing speed of between 1 m/s to 10 m/s, however a layer of between 1 nm to 5 nm may be applied with a relatively more uniform deposition to the substrate to which evaporated source material can be bonded to increase the thickness of the deposited layer.

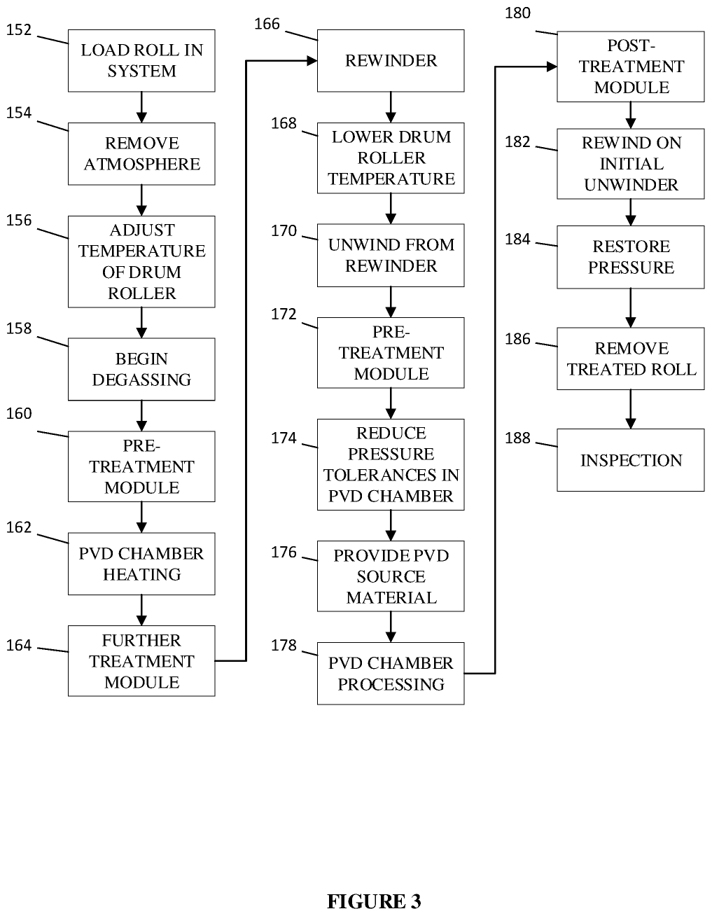

As discussed above, the system 10 may be used for a two stage processing method. Referring to FIG. 3, there is illustrated a flow chart for a two stage processing method. Generally, the two stage method comprises one or more degassing stages, and a subsequent PVD processing stage. Each stage of processing may be conducted within the system without repressurising the system until processing is complete. However, in some embodiment, the system may be repressurised between stages.

The system 10 is loaded with a roll 2 of textile 152 to be processed. The system is then sealed and atmosphere removed 154 from the vacuum chamber 22. As the atmosphere is removed from the chamber 22, the other components within the chamber may be heated or cooled to a desired temperature. For example, the cooling systems may be cooled to around −100° C. and the coating drum 120 may be heated to around 10° C. 156. Conventionally, a coating drum 120 is maintained at a temperature of −1° C. to assist with condensation of an evaporated source material. However, it is desired by the method of the present disclosure to increase the temperature of the coating drum 120 to allow for degassing to occur.

Once all components of the system have been brought to a desired temperature, and the desired pressures have been achieved in the vacuum chamber 22, the roll can begin the degassing process 158. The system pulls the textile 1 from the roll 2 through the processing line towards the rewinder 132 at the end of the process. The textile 1 first passes through the pre-treatment module 160 towards the PVD chamber. In this initial stage of processing, the system has activated the evaporator apparatus, however no PVD source material is provided into the system 10 and the coating drum may also be heated 162. The heat from the drum 120 and the evaporator apparatus 116 raise the temperature of the textile 1 to cause degassing of the moisture in said textile 1. The drum temperature for degassing may be in the range of 0° C. to 30° C., or 1° C. to 20° C., or 2° C. to 10° C. or around 5° C. The preferred speed of processing a textile during degassing may be in the range of 0.5 m/s to 10 m/s, or may be 0.5 m/s to 8 m/s, or may be, 0.5 m/s to 5 m/s, or may be 0.5 m/s to 3 m/s. It will be appreciated that exposure to a heat source for smaller amounts of time is likely to decrease the effectiveness of degassing and also raise the pressures within the PVD chamber above desired thresholds. The temperature of the coating drum 120 is preferred to be as high as possible while also maintain a pressure below a shutoff pressure, but preferably below a temperature which can damage the substrate. It will be appreciated that each textile 1 may have a different temperature threshold and the system may be programmed to ensure that safe operating temperatures of the coating drum 120 for a predetermined textile 1 introduced into the system are not exceeded. Using the PVD chamber and pre-treatment modules 104 allows for the textile to be degassed as a substrate 1 rather than a roll 2.

Commonly, rolls 2 of substrate film can be partially dried prior to PVD treatment by using heating rooms or other drying machines. However, due to the larger surface area of textiles 1 compared with paper substrates or film substrates, such as PP or PET, typically coated via PVD processes the drying times are more time consuming, more costly and may not achieve a desired moisture content adequate for PVD processing. The larger surface area of the textile 1 is due to the apertures and structures formed by the weave, braid, or un-woven nature of the textile substrate. Degassing as a substrate 1 rather than as an entire roll 2 is more effective at degassing a textile with a porous structure which can improve the quality of PVD treatments. Further, it is more cost effective to dry and treat a substrate at a desired PVD processing time, than to heat a drying room with one or a plurality of rolls which may again be left exposed to atmospheric conditions after drying and before PVD processing.

A further treatment module may be provided after the PVD chamber 164 which can allow for plasma treatment of the textile 1 after exiting the PVD chamber and before rewinding. Optionally, cooling systems can be provided either side of the PVD chamber which can capture degassed contaminants. Once all treatments have been completed on the substrate, the substrate is rewound on the rewinder 166. At this time the substrate will be degassed to a sufficient moisture content which will be suitable for PVD treatments. If the moisture content is still not at a desirable level, the system may pass the substrate through the system a further time to further degas the textile 1.

It is preferred that the substrate being processed is degassed such that the moisture content of the substrate is between 6% to 0.1% by wt or by volume, or between 5% to 0.2% by wt or by volume, or between 4% to 0.3% by wt or by volume, or between 3% to 0.4% by wt or by volume, or between 2% to 0.5% by wt or by volume. It is preferred that the moisture content is reduced to a predetermined percentage such that a desired speed of processing can be achieved. It will be appreciated that the slower the textile speed, the thicker the deposition onto the substrate may be. As such, coatings of between 100 nm to 50 nm can be obtained with faster speeds which the two stage process may achieve. It is preferred that the system may be adapted to deposit source materials with a thickness of between 1 nm to 1000 nm, but more preferably in the range of 10 nm to 200 nm, or even more preferably 30 nm to 100 nm.

Once the textile 1 has a suitable moisture content for PVD treatment, the temperature of the coating drum 120 is decreased to around −1° C. to −10° C. 168, but more preferably is around −5° C., and the textile 1 can undergo the desired PVD treatment processes, or stage two.

In this embodiment, the rewinder of the system 10 can also function as an unwinder, and the unwinder 102 can also function as a rewinder. In this way the textile 1 can be passed from one end of the system 10 back through to the starting end of the system 10. As such, the system 10 is adapted to retain a tail end of the textile 1, which may be fixed to the roll of the unwinder 102, and use this as the lead portion for processing in stage two for PVD processing. Generally, the textile may be fixed to a roll on the unwinder 102 and a roll on the rewinder 132 and the textile can be processed between the rolls. As the substrate 1 is unwound from the rewinder 170, the the textile 1 preferably passes through a pre-treatment module 172 to activate the surface of the textile or to sterilise the textile. The pre-treatment module 104 may be a plasma module 104 which can generate a plasma suitable to for the pre-treatment process.

As the textile 1 is being processed to apply a PVD coating, a maximum pressure internal the PVD chamber 110 cannot be exceeded. As such, the pressure thresholds are lowered 174 to ensure that a maximum pressure is not exceeded within the chamber 110. As the substrate 1 enters into the PVD chamber, a PVD source material can be vaporised 176 and the vapours are directed to the substrate 1 and are deposited thereon 178.

Optionally, a post-treatment module 104 may be provided after the PVD chamber 110 which can again treat the substrate with a desired treatment process 180. It is preferred that the treatment process is a plasma treatment which may enhance bonding of the deposition to the textile 1. The textile 1 can then be rewound on the unwinder 102 (which functions as a rewinder also) 182. The pressure can then be restored 184 to the chamber 22 and the treated roll 2′ removed 186 and inspected 188 at a later time.

Optionally, after PVD processing at step 178 or after the post-treatment 180, the substrate may undergo a CVD treatment (including PECVD treatments), which may apply a functional coating to the textile 1. CVD treatments may also be applied in advance of the PVD processing step to apply a functional coating or a binder to a textile 1. More than one CVD treatment may be provided to apply a functional treatment to the PVD coated textile 1. Optionally, the system is adapted to apply a CVD coating to both sides of the textile 1, which may require one or more CVD processing stations. Functional coatings applied via CVD processes may include at least one of a; hydrophobic coating, hydrophilic coating, protective coating, transparent coating, UV coating, or any other predetermined functional coating. If CVD processes are used, a separate chamber may be provided to allow for CVD processing.

In another embodiment, the textile may be pre-coated before deposition processing. Pre-coatings may include primer coats or functional coatings. Functional coatings may be used to improve adhesion between the textile and the deposited source material. Primers may be used to seal yarns or fibres to reduce oils or other residues from being outgassed or seal oils or other residues under the primer, which may improve the deposition quality and durability of a deposition coating. Primers may be generally invisible or generally transparent such that little to no variation of the face of the textile is altered if the textile is to be used as a viewable material, such as use as the face material in a garment. Primers may form a shell or coating on yarns and/or fibres. Oils or other residues on yarns and fibres may be present from dyeing processes or manufacture processes and may cause pressures to increase during deposition processing, the presence of these oils or residues may also reduce adhesion between the textile and deposited source material by acting as an interface between the deposited source material and textile. In some embodiments, oils need only be contained during deposition, and primers may be allowed to degrade, crack, or otherwise allow transition of oils after deposition.

In addition, the system 10 may utilise more than one deposition chamber (PVD, PEPVD, CVD, PECVD), or more than one deposition station within the same chamber, which may allow for multiple coatings to be performed and overall increase the speed of processing. If the system utilises more than one chamber, or deposition station, the system may be adapted to apply multiple treatments to a textile 1 in a single stage of processing or apply a treatment to both sides of the textile 1. Optionally, the system 10 may allow for the textile sides to be swapped if the system winds and unwinds the textile 1 such that the side to be treated

As the textile 1 has now been treated with the desired processes, the roll 2 may not be required to be stored in strict moisture control conditions as those prior to PVD coating. However, it may be advantageous to cover the substrate such that the substrate is not exposed to contaminants, such as dirt, water, or weather conditions.

The above process may have significant benefit with respect to textile 1 processing. Notably, using standard degassing outside of the system and then processing a substrate with the system 10, the speed in which processing may be achieved is in the range of 0.5 m/s to 0.8 m/s. However, using the two stage method as described above, the textile 1 can be treated at speeds of 1 m/s to 6 m/s, which is a significant advantage over existing methods and systems.

In another embodiment, the system 10 may be connected to a vacuum storage chamber (not shown) which can be used to store partial vacuum pressures to reduce vacuum time. The vacuum storage chamber is preferably the same size as or larger than the winding chamber 128, and PVD chamber 110. The vacuum storage chamber can be connected to the system 10 such that when processing is complete in the vacuum chamber 22 of the system a valve can be opened to equalise the pressures between the vacuum storage chamber and vacuum chamber 22 of the system 10 and thereby a portion of the vacuum can be stored for subsequent batch processing. Once the chamber pressures are equalised, the valve can be closed between the storage chamber and chambers 101, 110. Winding chamber 128 and PVD chamber 110 can then be brought back to atmospheric pressure and substrates within can be removed. During this time, if there is a further batch to be processed by the system 10, a pump may optionally be activated to remove atmosphere from the vacuum storage chamber while the processed substrate is unloaded and a new substrate is loaded into the system 10. Once the new substrate has been loaded in the system, the vacuum chamber valve may be opened again to equalise pressures. Once pressures are equalised, the valve can be again closed and the PVD chamber 110 and the winding chamber 128 can be pumped to remove atmosphere to begin the next batch processing. This is a significant advantage as this system can save energy and time by storing a partial vacuum pressure for subsequent batches. This type of system may also reduce the time required to repressurise the PVD chamber 110 and winding chamber 128 compared with conventional systems.

The valve between the chambers 101, 110 and the storage chamber is preferably a fluid tight valve such that pressures can be stored for a period of time and saved for subsequent batch processing. Optionally, the vacuum storage chamber has an emergency vent which is adapted to open if vacuum pressures are to be brought back to atmospheric pressures.

If the two stage process is to be used with conventional systems, the chamber may be re-pressurised after a first treatment stage to dismount the roll 2 from the winder 132, and mount on the unwinder 102 before a further processing stage. While using a conventional system may have overall longer processing times compared with a system which can wind and unwind between the unwinder 102 and the winder 132 a plurality of times, a deposit of a desired PVD source material can be applied to a textile 1 successfully, which cannot be achieved as readily or efficiently by known processing methods with known systems.

Processing Line Moisture Control Devices

In advance of a textile 1 arriving at a PVD processing system, the textile will have likely undergone at least one of a coating process, dyeing process, or treated with a functional treatment. The textile will then be transported to a PVD processing system, which may or may not be within the same manufacturing plant. Regardless of whether the same plant is for these other treatment processes, the textile 1 is likely to be in a queue or stored for a period of time before PVD processing begins. This may be a period of days, weeks or months, and during this time the textile 1 is exposed to ambient atmosphere, humidity conditions or even left exposed to outside weather conditions. If textiles are exposed to outside conditions, cleaning chemicals are generally used to treat a textile 1 before further processing. These chemicals may dangerous or adverse to the environment, and reduction of use of these chemicals may be desirable. Further, textile storage places may or may not have secure environments or be environments free from contaminants or unclean conditions.

In view of the above, there are a number of sources of impurities and contaminants to which the textile 1 may be exposed. The following devices may improve the overall quality of a textile 1 for PVD and/or CVD treatments, and may also be beneficial in relation to storage of textiles 1 for later use. It will be appreciated that PVD or CVD treatments may typically be near to the end of the treatment processes for a textile before being turned into a final product, such as a garment.

A first device to control textile roll 2 exposure may be a bagging system. A textile 1 will typically be dried by a stenter (after dyeing) which can be used to remove a significant amount of moisture within the textile 1 and set the dye within said textile. After being processed by the stenter, the textile will generally be deposited into a trolley and moved to an inspection apparatus. A trolley may include a bin, tub, plastic trolley, platform trolley, batching trolley, wooden platform trolleys, luggage trucks, refuse barrows, beam trolleys, or any other movable receptacle suitable for moving textiles. Typically, the time between being deposited into a trolley and inspection of the textile 1 may be in the range of 3 to 24 hours after exiting the stenter, although longer times may also be encountered. During this time, the textile 1 will be exposed to open atmosphere conditions, the textile 1 will start absorbing moisture within local atmosphere until the textile reaches a natural moisture content, or a moisture content near thereto depending on local temperatures and humidity. It is preferred that the textile 1 is inspected as soon as possible such that creases in the textile are minimised, and ingress of moisture into the textile 1 is limited, however as inspection times may not always fit into schedule systems should be in place to assist with moisture reduction.

The trolley 200 may be a constructed with a platform with a plurality of wheels 208 and at least one wall which may assist with desired placement of the textile and retaining the textile within the trolley 200. Preferably, the trolley 200 comprises at least three wheels 208, but more preferably at least four wheels 208.

At least four walls 204 may be used to retain the textile 1 with the platform 202 of the trolley 200 being of a dimension which is equal to or greater than that of the textile 1 width. The walls 204 of the trolley 200 preferably meet at a rim (shown as upper rim 206), which defines an opening 208 of the trolley 200 for receiving the textile 1 or substrate therein. The rim 206 may be relatively wider than the walls and a flange 210 may extend therefrom which can be used to reinforce the walls or maintain a desired wall 204 shape when the trolley is loaded is a substrate, liquid or other material to be deposited therein. The walls 204 may have a reinforcing means, such as splines or ribs which may improve the integrity of the trolley 200. Splines or ribs may be integrally formed with the walls 204.

Optionally, the trolley walls may be a metal a cage (as seen in FIG. 5) with which can receive a flexible bag 201 therein which can be used to receive the textile 1. The flexible bag can be supported by the walls 204 and covered or sealed after a textile 1 has been deposited therein.

Closed Trolley

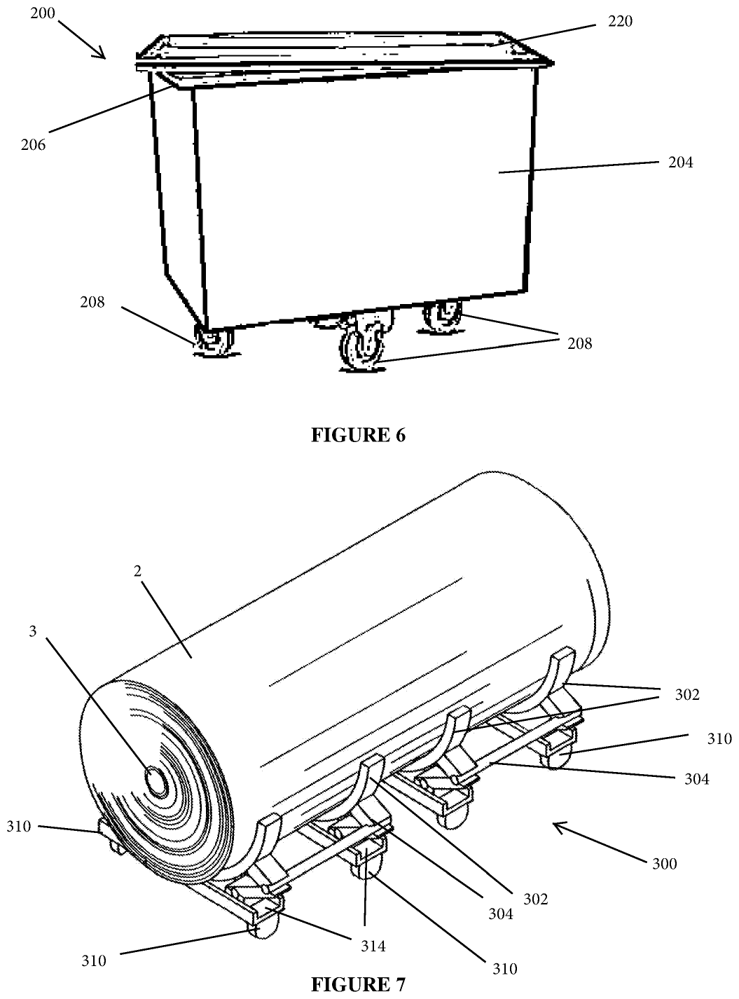

Referring to FIG. 6 there is illustrated a closed trolley system. The closed trolley system comprises a cover or ceiling for the trolley to reduce the ingress of atmosphere into the trolley. The cover is preferably fitted with a gasket or other sealing means which provides a superior seal against external atmosphere. The gasket of the cover will generally conform to the shape of an upper rim of the trolley. Optionally, multiple concentric or coaxial gaskets may be provided which assist with forming a seal between the cover and the trolley. In another embodiment, the gasket may be of an irregular or wavy shape which can cover a greater portion of the rim of the trolley.

Each gasket will preferably be seated within a depression or groove which can retain the gasket in a desired shape and assist with forming a liquid-tight, air-tight or gas-tight seal with the trolley.

The walls 204 of the trolley 200 may be double walled with a void between the double walls 204. Optionally, the trolley may be a vacuum walled 204 receptacle such that moisture or condensation is less likely to form on the walls 204 of the trolley 200. Further, having vacuum walls may allow for heat to be retained for a longer period of time which may assist with outgassing of the substrate, which is preferably a textile 1. Again, as heat generally improves the outgassing rate of a substrate, the moisture content of the textile 1 may be further controlled.

The cover 220 may be a transparent cover which allows for viewing the interior of the trolley without requiring the removal of the cover. Preferably, the cover is formed from a polymeric material, such as Perspex, PVC, ABS, LDPE, HDPE, PP, PS, PET, TPU or any other desired polymer. Preferably, the cover is formed as a rigid structure which can span across the opening of the trolley defined by the rim.

As moisture control for textiles is generally not a primary concern for textile uses, the trolley system as described above is a novel improvement over existing trolley transport systems as moisture control can be obtained, which may also assist with reducing external contaminants from coming into contact with a textile undesirably.

Further, it will be appreciated that during the inspection stage, the textile 1 may be mounted to inspection apparatuses directly from the trolley 200 and onto a winder. The winder may be used to form a roll of the textile or substrate which may then be sealed within a vacuum bag, or fluid-proof or moisture impermeable bag 400 (discussed below).

As the cover is generally adapted to form a seal, a one-way pressure release valve may be provided in the cover such that removing the cover can be possible at a desired time as when the substrate cools, the internal pressure of the trolley may be different than that of the ambient local atmosphere which can cause suction. Other means for equalising pressure may also be used with the cover if desired.

Bag System Trolley

In another embodiment, the trolley 200 can be fitted with a sealable trolley bag 201. A sealing means of the trolley bag 201 is disposed near to the opening, and can be used to provide a fluid tight seal to prevent ingress of moisture or other contaminants. The sealing means may be similar to a Ziploc™ bag seal in which a protrusion (or tongue) be fitted into a groove to form a seal therebetween. Other suitable tongue in groove seals may also be used with the bag system trolley 200. Another suitable seal may be a heat pressed seal which can be formed by a heating element clamping the trolley bag 201. If a heat pressed seal is used, it is preferred that the seal is a sacrificial seal such that the trolley bag 201 may be reused a plurality of times.

In another embodiment, a drawstring system may be used to form choke point for the trolley bag 201 with a clamping seal used to seal the bag to form said fluid tight seal. Optionally, instead of a fluid tight seal, the trolley bag 201 may be provided with a liquid tight seal. It will be appreciated that the seals in some embodiments may be opened and closed a plurality of times without reducing the integrity of the seal for the bag.

In yet another embodiment, the trolley bag 201 may be act similar to that of a membrane and may allow for moisture to exit from inside the bag to the outer atmosphere after the bag has been sealed.

Suitable polymers for forming the bag include at least one of; PVC, PP, PET, ABS, LDPE, HDPE, PS, TPU or any other desired polymer. Preferably, the polymer selected is a moisture vapour impermeable material such that moisture cannot enter into a sealed trolley bag 201 or is greatly reduced. For example, the trolley bag 201 may be formed with a metal layer, or a metal film similar to that applied to food stuff packaging. As the trolley bag 201 is adapted to cover or enclose a textile 1, the trolley bag 201 is preferably formed from a flexible polymer such that the bag can be wrapped around the textile 1 and subsequently vacuumed to remove the atmosphere internal the trolley bag 201. The atmosphere removal system may be similar to conventional travel vacuum bags with a one way valve on the exterior of the trolley bag. The valve can have a vacuum or other conventional pumping or sucking means used to remove the atmosphere internal a sealed trolley bag. Once a desired amount of atmosphere has been removed the valve can be sealed and the textile 1 can be stored for a desired length of time before inspection.

It is preferred that the trolley bags 201 are reusable and may optionally be washable, autoclavable, or otherwise cleaned. Trolley bags may also be formed with an opaque coating to reduce UV radiation impacting the roll which may cause decolouration or weakening of the textile 1.

Suitable mounting means for the trolley bag 201 may also be provided on the trolley 200, such that the trolley bag 201 can be mounted to the upper rim 206 while the textile 1 is loaded. A suitable mounting means may include rings and hooks, hook and loop fasteners, adhesives, clamps or any other desired means.

Moisture Capture Trolley

In another embodiment, the cover comprises a moisture removing article. Filters or moisture capture means may be fitted to the cover of the trolley to allow moisture within the trolley to be captured.

A suitable moisture capturing means may include calcium chloride or another moisture capturing or moisture absorber material. The moisture capturing means is preferably provided near to the opening of the trolley 200 such that moisture entering into the trolley 200 is more likely to be captured before interacting the with the substrate within the trolley 200.

In another embodiment, filters may be provided to capture moisture rather than bags of moisture capture means. Filters may be replaced after a predetermined period of time to ensure that moisture capture is effective.

Alternatively, the cover can be fitted with a cooling system, such as a cryo-condensation trap. These types of traps are generally useful if the substrate is likely to have a significant waiting time before inspection, typically more than 12 hours. The power requirements of these devices may be quite intensive and therefore while these systems may assist with reduction of moisture, it is preferred that other systems as discussed herein are used to reduce energy consumption and allow for easy movability of the trolley. It will be appreciated that there is utility with regards to using a cryo-condensation trap system with a trolley.

Heated Trolley

In yet another embodiment, the trolley may be connected to a heating system which maintains a minimum internal trolley 200 temperature. The internal trolley temperature need only be within the range of 20° C. to 60° C. to allow for a sufficient desorption rate to be achieved to reduce moisture within the substrate during the period after leaving the stenter and waiting for inspection.

If the trolley is provided with a heating system, preferably elements to heat the trolley are provided in at least one of the walls and the floor of the trolley. Optionally, the heating device may instead be disposed on the cover of the device. As the heating elements require an energy source, the trolley may be connected to a power outlet to allow for energising of the heating elements.

Roll Cradle

In another embodiment, the substrate can be inspected as the substrate is leaving the stenter such that the substrate can be wound onto a roll immediately after exiting said stenter and thereby reduce or remove the need for a substrate 1 to be deposited into a trolley. The wound substrate can then be protected from external conditions by a bag as described below, or may be placed into a moisture control room to await inspection. If the substrate is rolled immediately after leaving the stenter, the roll can be moved by the use of a roll cradle. Although, a roll cradle will typically be used when the substrate has been rolled after inspection.

The textile or substrate is wound using a winder or other similar apparatus to form a roll 2. A roll 2 is a common way to store and transport textiles 1 and flexible substrates as this reduces the potential for creases to form in the textile 1 and also generally provides for close compaction of the textile 1 such that greater volumes of substrates can be stored, and insects and other undesired organisms are less likely to move between layers of the roll 2. A winder apparatus is common in the art and will be readily understood by persons of skill in the art as being a device to wind or roll up a substrate or textile 1. Once the textile 1 is wound into a roll 2, the roll 2 can be placed in a cradle 300. An embodiment of such a cradle 300 with a roll mounted thereon is shown in FIG. 7. The cradle 300 is sized and shaped to allow for mounting of a roll 2 for easy transport.

The cradle 300 as shown comprises a plurality of arms 302 adapted to support a roll 2. In an unillustrated embodiment, the cradle comprises a crescent shape or semicircle shape which can receive a roll 2. A support structure 304 is provided to support the arms 302 and the roll 2 thereon. The arms 302 may be shaped to conform to the diameter of a roll 2 as shown, or may be shaped to allow for mounting of any sized roll therein. The arms 302 as illustrated are rounded such that the arms 302 substantially conform to the roll shape.

The support structure 304 as shown has a plurality of casters 310 or wheels 310 which can be used to push or move the cradle 300. A locking means (not shown) or clamp may be provided for the wheels of the cradle 300 to reduce unwanted cradle movement when being loaded or when the cradle is being used to temporarily store a roll 2. The support structure 304 may be a tubular frame structure, or other structure which can receive loads of between 100 kg and 3000 kg or more.

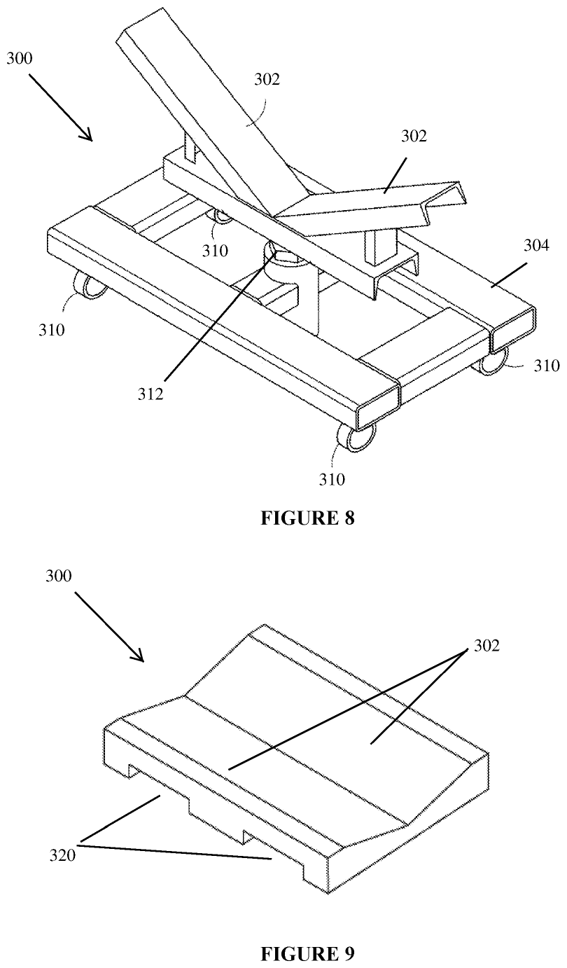

The arms 302 may be adapted to pivot or swivel relative to the support structure at a joint 312 (see FIG. 8). The joint 312 may be locked in place or free to rotate and may assist with movement of the cradle 300 on inclined or declined surfaces and may also assist with moving the roll around tight corners.

A plurality of cradles 300 may be used to support a roll 2. As shown in FIG. 7 two cradles 300 are being used to support the roll 2. Optionally, multiple cradles 300 may be connected together to support rolls 2 of any length. In one embodiment, the arms 302 may be moved relatively away from each other and locked in a desired position to support rolls 2 with a larger diameter. This embodiment can be seen in FIG. 7, in which the arms are allowed to move along tracks 314 above the wheels 310 and locked into a desired position. In addition, the height of the arms 302 may be altered to support a roll 2. The arm heights may be changed by hydraulic means, jack system, a crank or any other desired means.

While it is preferred that each cradle 300 has two pairs of arms or more, one pair of arms may be used as shown in the embodiment of FIG. 8. In this embodiment, two cradles 300 may be used to support a roll 2. Optionally, a roll support may be mounted onto the arms 302 which is a longitudinal support member which is generally semicircular in shape which allows the bottom of the roll to rest therein. Straps and/or tie-downs may be used to secure the roll during movement and assist with reducing the potential for toppling.

The cradle 300 will also preferably have a vacuum bag 400, impermeable flexible membrane or flexible bag over the mounting arms (or the longitudinal support member) of the cradle 300 such that a roll 2 can be mounted on the bag 400 on the cradle 300 and sealed therein. The bag 400 may provide a barrier between external environment and atmosphere while the substrate is stored and transported. This may assist with maintaining a more desirable moisture content and keeping rolls 2 clean before vapour deposition treatments. Suitable polymers for forming the bag 400 include at least one of; PVC, PP, PET, ABS, LDPE, HDPE, PS, TPU or any other desired polymer. Preferably, the polymer selected is a moisture vapour impermeable material such that moisture cannot enter into a sealed bag 400 or is significantly reduced. A lining may be provided in the bag 400 which may be similar to that used for food stuff packaging, in which a metal layer or metal film is provided. Other linings for the bag 400 may also be used depending on the purpose of the bag and the roll 2 which is to be received therein. The bag 400 may further comprise a membrane which can be hydrophobic or hydrophilic to assist with control of moisture in the bag 400.

Conventional roll transport systems do not provide a means to allow for application of a membrane or other bag device, as rolls are typically transported by inserting a lifting arm into a hollow core 3 of the textile 1. This is due to the fact that a bag would cover the core 3 of the roll, and not allow a lifting device to lift/move the roll 2, the cradle 300 of the present disclosure provides a significant advantage over the known devices in the art.

The support structure 304 preferably comprises hollow portions which allow for insertion of forklift forks to raise and lower the roll mounted thereon. Other lifting means may also be provided in the support structure such that conventional lifting equipment may be used with the cradle 300, such as pallet jacks.

Referring to the embodiment of FIG. 9, there is shown a further embodiment of a cradle 300. This cradle is more similar to a pallet which can be used to move a roll 2. The cradle 300 comprises a channel 315 in which a roll can be deposited. The channel may have arcuate sides or have linear sides as is shown in the illustrated representation. The inclined angle of the sides 316 will depend on the size of the roll and/or the size of the cradle 300. Optionally, the inclined angle of the sides may be manipulated by a jack system internal the cradle 300 which may be used to increase or decrease the inclined angle of the cradle to accommodate a desired roll 2. A pair of depressions 320 in the underside of the cradle may be used for mounting on forklift arms such that the cradle can be moved. It is preferred that the depressions 320 are formed generally perpendicular to the trough of the channel 315. Alternatively, the depressions 320 may be tunnels 320 or conduits which are formed through the cradle 300 which are preferably adapted to receive the arms of a forklift.

In the embodiment of FIG. 9, wheels 310 are not provided as the cradle is primarily transported by the use of a forklift. However, wheels 310 may optionally be mounted to the cradle 300 underside adjacent to the depressions 320.

The cradle 300 may be formed as a hollow ribbed structure or a structure or a frame structure with internal ribs or struts which allow for loading of a roll on the cradle 300 without failure. Suitable materials to form the cradle of this embodiment may be polymers, wood, metals, metal alloys, composites and fibre-reinforced plastic or resin. Optionally, securing points 322 may be provided on the cradle 300 which allow for mounting of straps, ties, or any other securing means to be mounted onto the cradle 300, which may be used to transport rolls more safely and reduce the potential for rolls to move during transit. Securing points 322 may include hooks, recesses, load bars, or any other suitable feature to allow mounting of a securing means.

In yet another embodiment, a frame portion is adapted to be positioned over a roll 2 mounted on the cradle 300. The frame portion may be adapted to abut the upper surface of the roll 2 such that the roll 2 is clamped between the cradle channel and the frame portion. The frame portion may be releasably connected to the cradle 300, and the frame portion may allow for mounting of a further cradle 300 thereon. With the frame portion, multiple rolls 2 can be stacked and stored more efficiently. A roll 2 mounted on a cradle 300 is preferably bagged (with a bag 400) to reduce ingress of moisture and/or external contaminants. If a frame portion has a further cradle 300 mounted thereon, the further cradle 300 and the frame portion can be releasably fixed together such that the frame portion and the further cradle 300 can be moved as a single structure.

Using a bag 400 is a significant advantage over known systems as substrates or rolls 2 may have long exposure times to moisture and/or contaminants in the atmosphere. Therefore, these exposure times may require additional cleaning or degassing processes before further treatments can be applied to the substrate or roll.

Preferably, a bag 400 is adapted to form a seal along the length of the bag which defines an opening 402. In this way the bag 400 can be wrapped circumferentially around the roll 2. The front end, back end and the length of the bag 400 may comprise a single sealing means to seal the bag. Preferably, the bag 400 can be vacuumed or have at least a portion of the atmosphere removed.

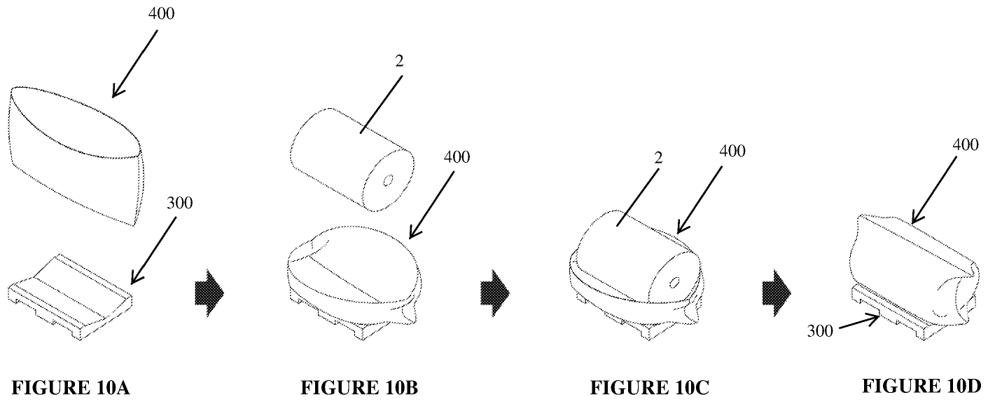

A method for mounting a bag 400 on a cradle 300 (similar to that shown in FIG. 9) is shown in FIGS. 10A to 10D. The method shows mounting a bag 400 onto said cradle 300 and mounting a roll 2 in the bag 400. The bag 400 as shown is formed from a sheet of material which has been folded over and fixed at the sides. An opening 402 is defined on the fourth side and is adapted to receive a roll. The bag opening 402 can be spread manually, or may be mounted to a cradle 300 in a spread configuration. The spread configuration is shown in 10B and may be maintained more reliably by ties (not shown) on the exterior of the bag 400 or a biasing means 412. The ties may be fixed to the outside of the bag 400 and may be used configure the bag into a spread configuration (open configuration) adapted to receive a roll 2. The ties may also be used to carry the bag 400 when the bag is empty. The roll 2 may be lowered into the open bag 400 by a crane, forklift or any other suitable means. When the bag 400 is in the spread configuration, a roll 2 can be lowered into the bag 400 and sealed therein. Ties may be fixed to the bag via adhesive, welding, ultrasonic welding, melting, fusing or otherwise bonding the ties to the bag. It is preferred that stitching is not used to fix the ties to the bag 400, as this may result in leakage points.

Instead of ties, magnets may be provided which may be magnetised to a cradle 300. The magnets may be mounted to the bag to hold it open and removed after loading of the roll 2. The magnets may alternatively be provided in the cradle 300 and are electro-magnets which can be turned on and off to allow release of a bag being retained.

Once the bag 400 has been sealed, the air and other fluids within the bag 400 can be at least partially removed. Conventional fluid removal means, such as a vacuum apparatus, may be used. The bag may be considered to be a form of vacuum packaging and may be fitted with a one way valve, or a direction selectable valve. Alternatively, a port may be provided on the bag (not shown) which can be opened and closed selectively. More than one valve or port may be provided which may assist with more effectively removing fluids from the bag 400.

In yet a further embodiment, the opening of the bag 400 comprises a biasing means 412 (such as that shown in FIG. 11) which can be used to temporarily bias the bag opening 402 in the spread configuration or bias the bag 400 in a closed or sealing position. The spread configuration of the bag 400 is illustrated in FIGS. 10B and 10C. The closed configuration of the bag 400 is illustrated in FIG. 10D and in this step the roll may be moved to a storage location or loaded onto a vehicle on the cradle 300. In this way, the cradle 300 can be used for storing and moving the roll 2. Cradles 300 are preferably adapted to allow cradles to be stored side by side or in close proximity. The length of a cradle 300, such as the pallet type cradle of FIG. 9, may be sufficient to contain the length of the roll such that there is no overhang of the roll 2 while on the cradle 300.

A sealing means is provided at the opening which can be used to form a fluid tight seal. Optionally, two or more fluid tight seals are provided at, or near to, the opening. The fluid tight seals may be any conventional sealing means to limit or prevent fluid ingress into a bag 400 or receptacle.

In yet another embodiment, the bag 400 may be formed as two semi-circular halves which can be fixed together to form a sealed bag. Again, any suitable sealing means may be provided to fix the halves together. Optionally, the halves may be integrally formed together, or may be separate halves. Using semi-circular portions to form the bag may allow for a bag with less overhang, or regions in which moisture may be present after sealing.

In yet another embodiment, a longitudinal bag 400 with an end opening 402 may be provided for a roll 2 which allows for conventional lifting means, such as the bag illustrated in FIG. 11. The embodiment of FIG. 11, shows a flexible bag 400 comprising a bag wall 408 with an opening 402 and a sealing means 404 at the opening 402. The sealing means 404 may be any suitable sealing means which can limit the ingress of moisture into the bag 400. As stated above, as rolls 2 are generally lifted by their cores, the bag 400 may be fitted with a tubular extension 410 (shown in dashed line) which can be passed through the core 3 of the roll 2 such that the bag and roll 2 therein can still be lifted. The tubular extension may also be sealed using the sealing means 404 at the opening after being correctly mounted to the roll 2.

One side of the tubular extension may be sealed such that the seal does not need to close an open end of the extension. Preferably, the tubular extension includes a reinforcing, such as a web, or polymer mesh. Optionally, the bag comprises regions of reinforcing, which may assist with resisting tears and damage to the bag when being moved or stored.

The wall(s) 408 of the bag 400 are preferably formed with from a polymeric material which is resilient, flexible and may comprise a reinforcing means. The reinforcing means may be a mesh or fibres embedded within the bag wall 408, or may be additional sections of thicker material near to stress locations of the bag, such as at corners, seams, welds or attachment locations. Optionally, the bag 400 may have a plurality of walls, such that if an external bag wall is damaged, an interior bag wall may still be suitable to protect the roll from atmosphere.

Application of this bag 400 around a roll 2 may require mounting of the bag 400 to the lifting device, such that the arm of the lifting device is fitted with the tubular extension. The roll 2 can then be lifted by the arm with the bag thereon and the outer wall of the bag 400 can be used to cover and seal the roll 2. It will be appreciated that in this way only a single side of the roll can have an arm inserted into the core 3.

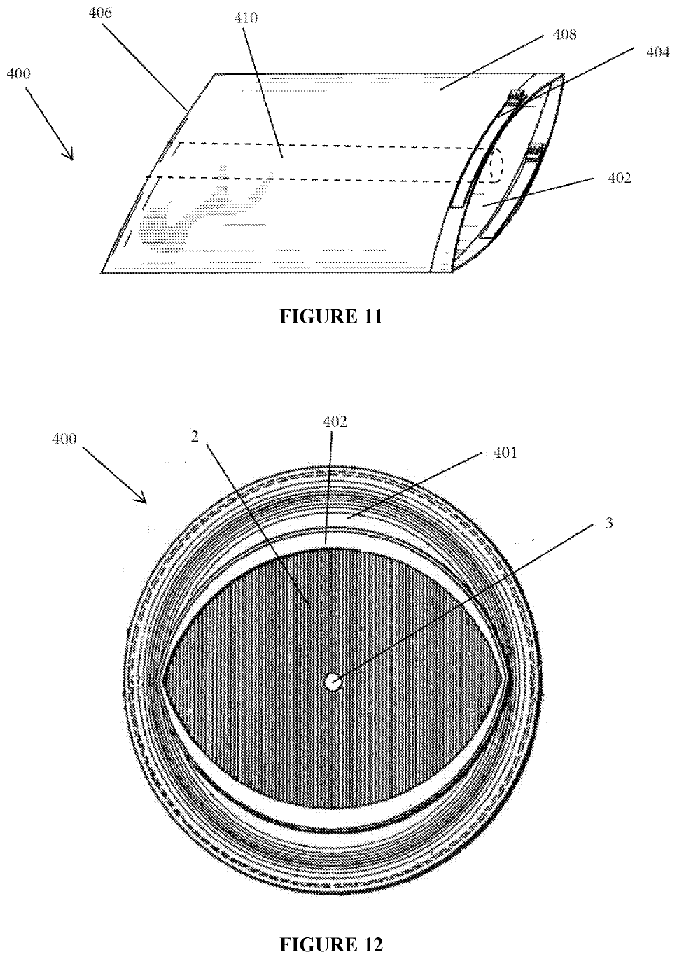

Referring to FIGS. 11 and 12, there are illustrated an embodiment of a roll 2 being bagged by a longitudinal protection bag 400. A core 3 of the roll 2 can be seen and may be accessed from the rear side 406 of the bag 400, with the core 3 receiving the tubular extension 410 of the bag therein. After sealing the bag 400 can be vacuumed or filled with a desired gas, such as nitrogen, ozone or another suitable dry gas which may assist with reducing the moisture within the bag.

While the bag 400 may be formed from a flexible polymeric material, the tubular extension 410 may be formed with a more rigid structure to more evenly fill the hollow core of the roll and reduce the potential for tearing or damage during movement or insertion of a lifting means.

As such, the trolley 200 and/or cradle 300 and/or bag system 400 as described above provides for an improved quality control and moisture control system which may lead to a superior final product after vapour deposition treatments. It will be appreciated that other treatment processes may also be advantageously improved by utilising at least one of the trolley 200, cradle 300 and/or bag system 400 as discussed herein.

Although the invention has been described with reference to specific examples, it will be appreciated by those skilled in the art that the invention may be embodied in many other forms, in keeping with the broad principles and the spirit of the invention described herein.

The present invention and the described preferred embodiments specifically include at least one feature that is industrial applicable.

1. A system for treating a substrate, the system comprising;
an unwinder adapted to receive and unwind a roll of substrate;
a rewinder adapted to rewind the substrate from the unwinder;
a physical vapour deposition (PVD) apparatus;
a vacuum chamber in which the unwinder, PVD apparatus and rewinder are disposed; and
wherein a coating drum of the PVD apparatus has a temperature of between 0° C. and 10° C., and is adapted to increase a desorption rate of the substrate.

2. The system as claimed in claim 1, wherein the textile can be unwound from the unwinder and wound at the rewinder, and unwound at the rewinder and wound at the unwinder.

3. The system as claimed in claim 1, wherein the vacuum chamber comprises a winding chamber with a first pressure, and a PVD chamber with a second pressure.

4. The system as claimed in claim 1, wherein the unwinder is also a further rewinder.

5. The system as claimed in claim 1, wherein the rewinder is a further unwinder.

6. The system as claimed in claim 1, wherein system comprises at least one plasma treatment module positioned adapted to generate a plasma.

7. The system as claimed in claim 1, wherein the temperature of the drum is dynamically adjustable.

8. The system as claimed in claim 1, wherein the system is adapted to at least partly degas the substrate by exposing the substrate to a heated boat of the PVD apparatus.

9. The system as claimed in claim 1, wherein the system further comprises a measuring roller.

10. The system as claimed in claim 1, wherein the system further comprises a thickness measurement unit.

11. The system as claimed in claim 1, wherein the system can pass the substrate between the unwinder and winder a plurality of times, while maintaining a vacuum in the vacuum chamber.

12. The system as claimed in claim 1, wherein a first feeder is provided at the unwinder and a second feeder is provided at the rewinder, each feeder being adapted to retain a portion of the substrate to reverse the direction of treatment of the substrate.

13. The system as claimed in claim 1, further comprising a cooling system for capturing degassed contaminants.

14. The system as claimed in claim 1, wherein the system is connected to a vacuum storage which can store at least a portion of the vacuum from the vacuum chamber.

15. A method of degassing and applying a PVD treatment to a substrate using a system, the method comprising a degassing stage and a physical vapour deposition (PVD) stage;
the degassing stage comprising the steps of;
mounting a roll of substrate on an unwinder in a vacuum chamber;
sealing the chamber and removing atmosphere from the vacuum chamber to a predetermined pressure;
heating a coating drum of a physical vapour deposition (PVD) apparatus to 10° C. and activating a heating boat;
passing the roll of substrate through the system such that the substrate is heated by the coating drum and heating boat to degas the substrate;
rewinding the substrate after heating; and
the PVD stage comprising the steps of;
unwinding the substrate and passing the substrate back through the system and evaporating a PVD source material to cause a deposition of the PVD source material on the substrate; and
rewinding the substrate into a roll.

16. The method as claimed in claim 15, wherein the substrate is passed through a pre-treatment module before being deposited with a PVD source in the PVD stage.

17. The method as claimed in claim 15, wherein pressure in the system is reduced for the PVD stage.

18. The method as claimed in claim 15, wherein the method further comprises measuring the thickness of the deposition.

19. The method as claimed in claim 15, wherein the method further comprises the step of passing the substrate through a post-treatment module to provide a finish to the deposition on the substrate.

20. The method as claimed in claim 15, wherein the system is adapted to perform two degassing stages.
